(19) United States
(12) Patent Application Publication
(10) Pub. No.: US 2008/0143248 A1
(43) Pub. Date: Jun. 19, 2008

(54) ORGANIC LIGHT EMITTING APPARATUS AND METHOD OF PRODUCING THE SAME

(75) Inventors: Taro ENDO, Kawasaki-shi (JP); Kohei Nagayama, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/945,638

(22) Filed: Nov. 27, 2007

(30) Foreign Application Priority Data
Dec. 15, 2006 (JP) 2006-337847
Nov. 14, 2007 (JP) 2007-295265

(51) Int. Cl. H01L 27/28; H01L 51/56

(52) U.S. Cl. 313/504; 445/25

(57) ABSTRACT

The present invention provides an organic light emitting apparatus having a liquid moisture absorbing member, the apparatus being capable of having a larger area than an organic light emitting apparatus having a same size substrate and without the liquid moisture absorbing member and of obtaining stable device characteristics without impairing the advantage of the liquid moisture absorbing member, in other words, by narrowing a non-light emitting region, and a method of producing the apparatus. The organic light emitting apparatus of the present invention has a side where a drive circuit is formed and a side where the drive circuit is not formed, and each of a starting point and an ending point of the application of the moisture absorbing member is placed on the side where the drive circuit is formed.

### BACKGROUND OF THE INVENTION

1. Field of the Invention

The present invention relates to an organic light emitting apparatus including an organic light emitting device having an organic compound layer placed between a pair of electrodes formed of an anode and a cathode, and a method of producing the apparatus.

2. Description of the Related Art

It is generally known that, when water infiltrates into an organic light emitting device (which may hereinafter be abbreviated as “device”) having an organic compound layer placed between a pair of electrodes, the device no longer emits light. In view of the foregoing, in order that the lifetime of the device may be additionally long, a moisture absorbing member capable of absorbing water is formed in the device to suppress the degradation of the device.

A method of forming the moisture absorbing member is, for example, a method including bonding a sheet-like moisture absorbing member to a sealing substrate, or a method including applying a liquid moisture absorbing member having a high viscosity to a sealing substrate.

The sheet-like moisture absorbing member has the following advantages: the member can be used only by being bonded to the sealing substrate, and can be easily produced. However, the moisture absorbing member cannot be placed in a space narrower than 1 mm because even the narrowest width of the sheet shape of the member is about 1 mm, and therefore a non-light emitting region expands. Two organic light emitting apparatuses are produced by using a same size substrate and with or without using the sheet-like moisture absorbing member. The apparatuses have the same panel area. When the respective areas of their light emitting regions are compared with each other, the area of a light emitting region of the organic light emitting apparatus produced by using the sheet-like moisture absorbing member comes to narrow. This is disadvantage.

On the other hand, the method including applying a liquid moisture absorbing member can narrow a non-light emitting region because a liquid moisture absorbing member can be formed even in a narrow space of 1 mm or less with a dispenser (drawing applicator). Two organic light emitting apparatuses are produced by using a same size substrate and with or without using the liquid moisture absorbing member. The apparatuses have the same panel area. When the respective areas of their light emitting regions are compared with each other, the area of a light emitting region of the organic light emitting apparatus produced by using the liquid moisture absorbing member can be expanded. This is advantage. However, the liquid moisture absorbing member has the following disadvantage: the shape of the moisture absorbing member is not constant, so a certain time period is needed for the adjustment of a method of forming the moisture absorbing member including a condition under which the moisture absorbing member is ejected from the dispenser.

In addition, the stage at which the shape of the moisture absorbing member is difficult to control in the application of the moisture absorbing member is the stage at which the shape of the moisture absorbing member changes at the time of the initiation or completion of the application; the shape of each of the initial point and end point of the moisture absorbing member is unstable at the time of the ejection of the member. Accordingly, the advantage of the application type moisture absorbing member, that is, the fact that the member can be formed in a narrow space may be impaired. In view of the foregoing, a method of controlling a dispenser has been proposed for additionally stabilizing the shape of the moisture absorbing member at the time of each of the initiation and completion of the application (see Japanese Patent No. 3,692,534).

The proposal relates to a method of applying a moisture absorbing member shown in FIGS. 7A to 7C.

First, as shown in FIG. 7A, on a sealing substrate 100, a pressure 103 of a nitrogen gas is applied from the upper end portion of a dispenser 101 toward the sealing substrate 100. A liquid moisture absorbing member 102 having a high viscosity and charged into the dispenser 101 is ejected by the pressure 103 from the tip portion of the needle of the dispenser 101 toward the sealing substrate 100, and the dispenser 101 is moved in the right direction.

Next, as shown in FIG. 7B, the dispenser 101 is further moved in the right direction, and the pressure 103 applied to the dispenser 101 is removed. At this time, the ejection of the moisture absorbing member 102 is terminated.

In the foregoing state, as shown in FIG. 7C, the dispenser 101 is further moved in the right direction. The moisture absorbing member 102 applied to the side of the sealing substrate 100 is applied in a dragged manner to be of a thin shape in association with the movement of the dispenser 101 because the moisture absorbing member 102 is not newly ejected from the dispenser 101. The unstable shape of the moisture absorbing member at the time of the completion of the formation of the member is controlled by the method.

In addition, an organic electric field light emitting panel described in Japanese Patent Application Laid-Open No. 2004-6286 is an invention that aims to prevent a desiccant formed on a sealing substrate from contacting with an electroluminescence (EL) device formed on an opposing EL substrate owing to the deflection of the sealing substrate. In addition, the specification describes an example in which the desiccant is formed only in a region close to the peripheral portion of the EL substrate, and is not formed in any region distant from the peripheral portion. The specification describes that, at that time, a driver circuit and a portion where the circuit is connected with the outside are formed in the periphery of a display region (FIG. 1A).

In general, moisture absorption increases as the amount of a moisture absorbing member increases. In view of the foregoing, the formation of an additionally large amount of a moisture absorbing member on a sealing substrate is effective in lengthening the lifetime of a device. In addition, the viscosity of the moisture absorbing member is increased in some cases in order that an additionally large amount of the moisture absorbing member may be formed in a narrow space, in other words, the thickness of the moisture absorbing member may be increased. However, as the viscosity increases, the shape of the moisture absorbing member does not stabilize upon initiation of the application of the member, and the member widens in some cases. In addition, upon completion of the application, when a dispenser moves away from the sealing substrate, the moisture absorbing member deforms stringily, or the shape of the member does not stabilize, and the member widens in some cases. When such widened moisture absorbing member or deformed moisture absorbing member contacts with an organic light emitting device, a display failure occurs, and when such member contacts with an adhesive (sealing portion), a sealing failure or the like occurs; the contact of such member adversely affects the characteristics of the device.

In view of the foregoing, a moisture absorbing member needs to be applied to a wide space so that the moisture absorbing member may not contact with a light emitting portion or a sealing portion even when the moisture absorbing member widens or deforms. The need impairs the advantage of a liquid moisture absorbing member, that is, the fact that the moisture absorbing member can be formed in a narrow space to narrow a non-light emitting region.

### SUMMARY OF THE INVENTION

In view of the foregoing, the present invention provides an organic light emitting apparatus having a liquid moisture absorbing member, the apparatus being capable of having a larger area than an organic light emitting apparatus having a same size substrate and without the liquid moisture absorbing member (the apparatuses having the same panel area) and of obtaining stable device characteristics without impairing the advantage of the liquid moisture absorbing member, in other words, by narrowing a non-light emitting region, and a method of producing the apparatus.

To solve the above-mentioned problems in the related art, an organic light emitting apparatus according to the present invention includes: a substrate; an organic light emitting device formed on the substrate and having a first electrode, an organic compound layer, and a second electrode in a stated order from a side of the substrate; a drive circuit which is formed on at least one side of the organic light emitting apparatus outside a region on the substrate where the organic light emitting device is formed and which controls light emission of the organic light emitting device; a sealing substrate for sealing the organic light emitting device between the substrate and itself; and a moisture absorbing member applied linearly to an outer peripheral portion of the sealing substrate, the moisture absorbing member being applied from a starting point to an ending point, and both the starting point and the ending point being placed on the side where the drive circuit is formed.

A method of producing an organic light emitting apparatus according to the present invention includes: forming a first electrode, an organic compound layer, and a second electrode in a stated order on a substrate to form an organic light emitting device; forming a drive circuit for controlling light emission of the organic light emitting device on at least one side of the organic light emitting apparatus outside a region on the substrate where the organic light emitting device is formed; applying a moisture absorbing member having a viscosity linearly to an outer peripheral portion of a sealing substrate; and bonding the sealing substrate to the substrate so that each of a starting point and an ending point of the application of the moisture absorbing member is placed on the side where the drive circuit is formed.

The present invention provides an organic light emitting apparatus having a liquid moisture absorbing member, the apparatus being capable of having a larger area than an organic light emitting apparatus having a same size substrate and without the liquid moisture absorbing member and of obtaining stable device characteristics without impairing the advantage of the liquid moisture absorbing member, in other words, by narrowing a non-light emitting region, and a method of producing the apparatus.

Further features of the present invention will become apparent from the following description of exemplary embodiments with reference to the attached drawings.

### BRIEF DESCRIPTION OF THE DRAWINGS

FIGS. 1A and 1B are each a schematic view showing an organic light emitting apparatus according to each of Embodiment 1 and Example 1 of the present invention.

FIGS. 2A and 2B are each a schematic view showing an organic light emitting apparatus according to each of Embodiment 2 and Example 2 of the present invention.

FIGS. 3A and 3B are each a schematic view showing an organic light emitting apparatus according to each of Embodiment 3 and Example 3 of the present invention.

FIGS. 4A and 4B are each a schematic view showing an organic light emitting apparatus according to Embodiment 4 of the present invention.

FIGS. 5A and 5B are each a schematic view showing an organic light emitting apparatus according to Embodiment 5 of the present invention.

FIGS. 6A and 6B are each a schematic view showing an organic light emitting apparatus according to Embodiment 6 of the present invention.

FIGS. 7A, 7B, and 7C are each a schematic view showing a method of producing a conventional organic light emitting apparatus.

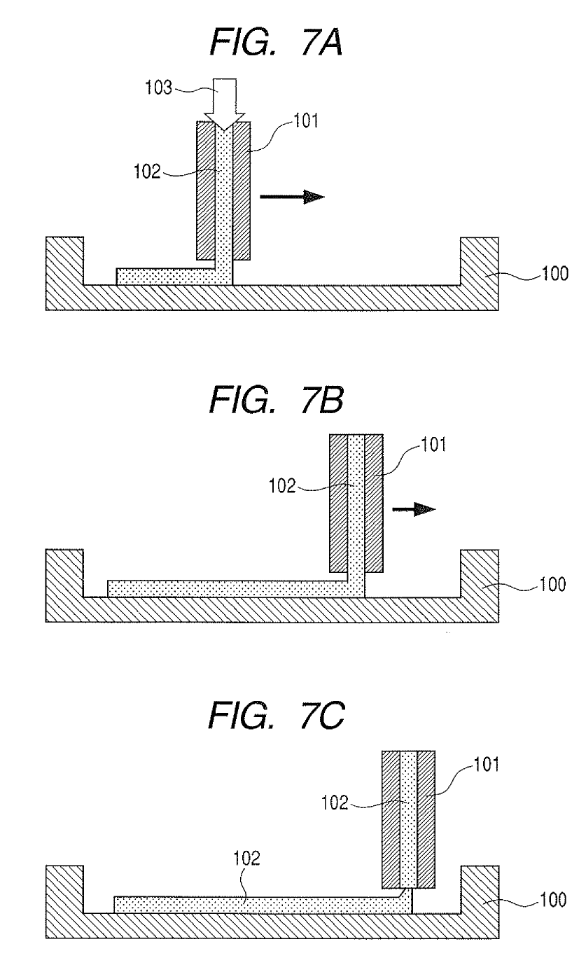

### DESCRIPTION OF THE EMBODIMENTS

Hereinafter, an organic light emitting device as an embodiment of the present invention will be described in detail with reference to the figures.

### Embodiment 1

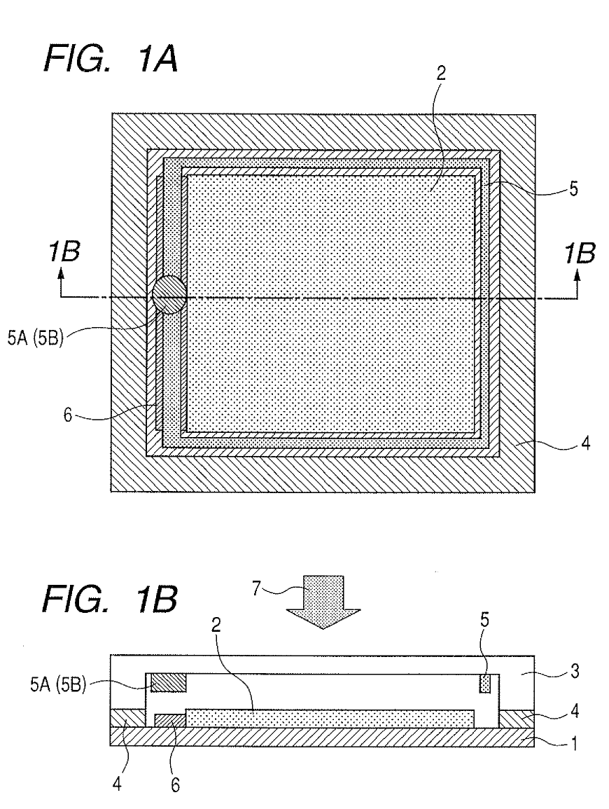

FIGS. 1A and 1B each show an example of Embodiment 1. FIG. 1A is a schematic plan view of an organic light emitting apparatus, and FIG. 1B is a schematic sectional view taken along the line IB-IB of FIG. 1A. In FIGS. 1A and 1B, reference numeral 1 represents a substrate; 2, an organic light emitting device; 3, a sealing substrate; 4, an adhesive; 5, a moisture absorbing member; 6, a drive circuit; and 7, an observation direction. Although FIG. 1A is a schematic plan view when FIG. 1B is viewed from the observation direction 7, the sealing substrate 3 is not shown in FIG. 1A in order that a planar constitution may be easily recognized.

The shown organic light emitting apparatus is produced as described below. A device substrate is formed to have such a constitution that a voltage is applied by the drive circuit 6 formed on one side of the organic light emitting apparatus to the organic light emitting device 2 placed between a first electrode (not shown) and a second electrode (not shown) on the substrate 1 so that the organic light emitting device 2 emits light. The drive circuit 6 refers to a circuit for controlling the light emission of the organic light emitting device, and is formed outside the region on the substrate 1 where the organic light emitting device 2 is formed. Then, the device substrate is covered with the sealing substrate 3 in which the moisture absorbing member 5 is formed with a drawing applicator, whereby the apparatus is produced.

Upon formation of the moisture absorbing member 5 in the sealing substrate 3 with the drawing applicator, an initial point (starting point) 5A and an end point (ending point) 5B of the application of the moisture absorbing member 5 each show an unstable shape at the time of the ejection of the member as described in the section titled “Description of the Related Art”. Accordingly, the moisture absorbing member 5 must be formed so that the member may not contact with, for example, the organic light emitting device 2 or the adhesive 4 to avoid degrading the light emitting characteristic of the apparatus even when the shape of the member changes. The change of the shape of the moisture absorbing member 5 is, for example, as follows: even when the initial point 5A of the moisture absorbing member 5 becomes thick, a non-light emitting region does not expand, and the end point 5B of the moisture absorbing member 5 becomes thick or changes into a stringy shape.

In view of the foregoing, in this embodiment, the moisture absorbing member 5 is formed so that each of the initial point 5A and end point 5B of the moisture absorbing member 5 may be placed on the side where the drive circuit 6 is formed. As a result, even when the end point 5B of the moisture absorbing member 5 becomes thick or changes into a stringy shape, the moisture absorbing member 5 does not contact with the organic light emitting device 2 or the adhesive 4 distant from the member, so the characteristics of the device are not affected.

In this embodiment, furthermore, the drive circuit is formed only on one side, and each of the initial point 5A and the end point 5B is positioned on the same one side. With such constitution, the area of a non-light emitting region can be additionally narrowed. Further, the organic light emitting apparatus produced by positioning both the initial point and the end point of the moisture absorbing member on the same one side can make a larger area of a light emitting region than an organic light emitting apparatus produced by, on the same size substrate, not positioning the initial point and the end point on the same one side.

On the other hand, the shape of the moisture absorbing member 5 during the formation is stable, and the moisture absorbing member 5 can be formed to be thinner than the initial point 5A and end point 5B of the member when viewed from the observation direction 7. Accordingly, a portion except the initial point 5A and end point 5B of the moisture absorbing member 5 is formed in a narrow non-light emitting region where the drive circuit 6 is not present.

Accordingly, the initial point 5A and end point 5B of the moisture absorbing member 5 which show unstable shapes and are apt to be thick are each formed on the drive circuit 6 as a relatively wide non-light emitting region. On the other hand, a portion except the initial point 5A and end point 5B of the moisture absorbing member 5 which shows a stable shape and can be formed to be thin is formed in a relatively narrow non-light emitting region, and the moisture absorbing member 5 is formed to surround a light emitting region. Therefore, the non-light emitting region of the moisture absorbing member 5 does not expand. Further, the organic light emitting apparatus produced by forming the initial point and the end point of the moisture absorbing member on the drive circuit can make a larger area of a light emitting region than an organic light emitting apparatus produced by on the same size substrate, not forming the initial point and the end point on the drive circuit.

A member of which the above-mentioned organic light emitting apparatus is formed by using an ordinary material.

A plastic film made of, for example, polyethylene terephthalate (PET), polycarbonate (PC), or polyether sulfone (PES), glass, quartz, or the like can be used in each of the substrate 1 and the sealing substrate 3.

It should be noted that the sealing substrate 3 is a member for sealing the organic light emitting device 2 between itself and the substrate 1. A planar substrate as well as a substrate the portion of which corresponding to a light emitting region is dug down can be used as the sealing substrate 3.

The first electrode and the second electrode are defined depending on the order in which the electrodes are formed on the substrate 1. An organic compound layer is formed between the first electrode and the second electrode, and a current is flowed between the electrodes, whereby the organic compound layer emits light. ITO, IZO, chromium, platinum, Al, Ag, or the like can be used as a material for each of the first electrode and the second electrode. When each of the electrodes doubles as a reflective layer, each of the electrodes is preferably formed of a material having high light-reflecting property. In addition, when any one of the electrodes is an electrode on a light extraction side, the electrode may be a transparent electrode. In the present invention, the first electrode and the second electrode may be an anode and a cathode, respectively, or the first electrode and the second electrode may be a cathode and an anode, respectively.

The organic light emitting device 2 may be a known device, and, for example, tris[8-hydroxyquinolinato]aluminum (Alq3) or N,N′-di(1-naphtyl)-N,N′-diphenylbenzidine (α-NPD) can be used in the device. The organic light emitting device 2 can be formed of a hole transporting layer, a light emitting layer, an electron transporting layer, and an electron injecting layer. Alternatively, the device can be formed only of a single layer, that is, a light emitting layer, can be formed of three layers, that is, a hole transporting layer, a light emitting layer, and an electron transporting layer, or can be formed of five layers, that is, a hole injecting layer, a hole transporting layer, a light emitting layer, an electron transporting layer, and an electron injecting layer.

The moisture absorbing member 5 is a member applied linearly to the outer peripheral portion of the sealing substrate 3 to absorb moisture present in a space between the substrate 1 and the sealing substrate 3. A material for the moisture absorbing member 5 is, for example, a water absorptive polymer, zeolite, or activated carbon. In order that a moisture absorbing member containing any such material may be applied and its thickness may be increased, the viscosity of the moisture absorbing member upon application is preferably 1.0×10³ cP or more to 1.0×10⁶ cP or less. This is because an excessively low viscosity makes it difficult to increase the thickness and excessively widens the member while an excessively high viscosity impairs the stability of the application and excessively widens the member in some cases. In order that the member may be applied to have an additionally narrow width, the viscosity is preferably 1.0×10⁴ cP or more to 1.0×10⁵ cP or less.

### Embodiment 2

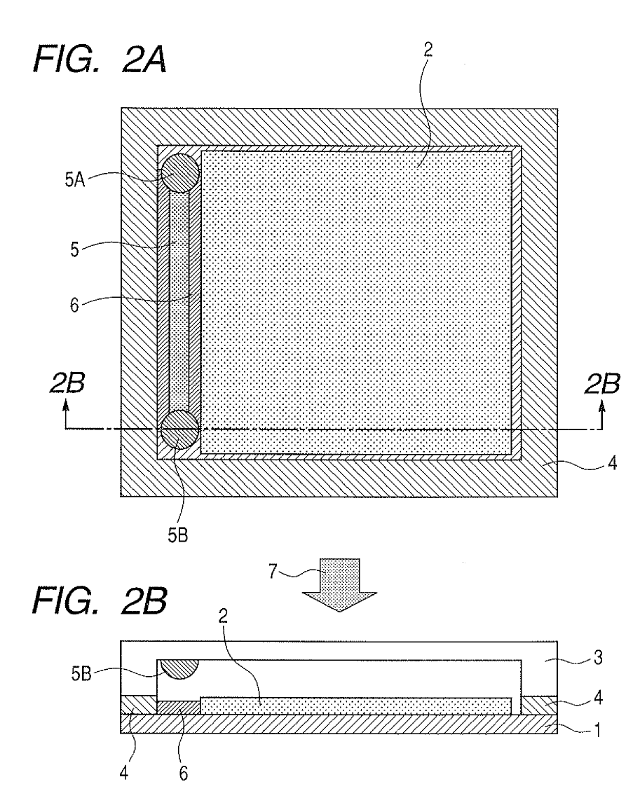

FIGS. 2A and 2B each show an example of Embodiment 2. FIG. 2A is a schematic plan view of an organic light emitting apparatus, and FIG. 2B is a schematic sectional view taken along the line 2B-2B of FIG. 2A. In the following figures, the same reference numerals as those of FIGS. 1A and 1B represent the same components as those of FIGS. 1A and 1B. Although FIG. 2A is a schematic plan view when FIG. 2B is viewed from the observation direction 7, the sealing substrate 3 is not shown in FIG. 2A in order that a planar constitution may be easily recognized. In addition, description similar to that of Embodiment 1 will be omitted.

The organic light emitting apparatus of this embodiment is also produced by steps similar to those of Embodiment 1 described above, but the moisture absorbing member 5 was formed only on the side where the drive circuit 6 formed on one side of the organic light emitting device 2 was formed. As a result, both the initial point 5A and end point 5B of the moisture absorbing member 5 are placed on the drive circuit 6. Accordingly, even when each of the initial point 5A and end point 5B of the moisture absorbing member 5 becomes thick, a non-light emitting region does not expand. Further, the organic light emitting apparatus produced by forming both the initial point and the end point of the moisture absorbing member on the drive circuit can make a larger area of a light emitting region than an organic light emitting apparatus produced by on the same size substrate, not forming the initial point and the end point on the drive circuit. Moreover, even when the end point 5B of the moisture absorbing member 5 changes into a stringy shape, the member does not contact with, for example, the organic light emitting device 2 or the adhesive 4, so the characteristics of the device are not adversely affected.

In addition, the entirety of the moisture absorbing member 5 of this embodiment occupies a narrow area, and a light emitting region can be expanded because the moisture absorbing member 5 is formed only on the drive circuit 6.

### Embodiment 3

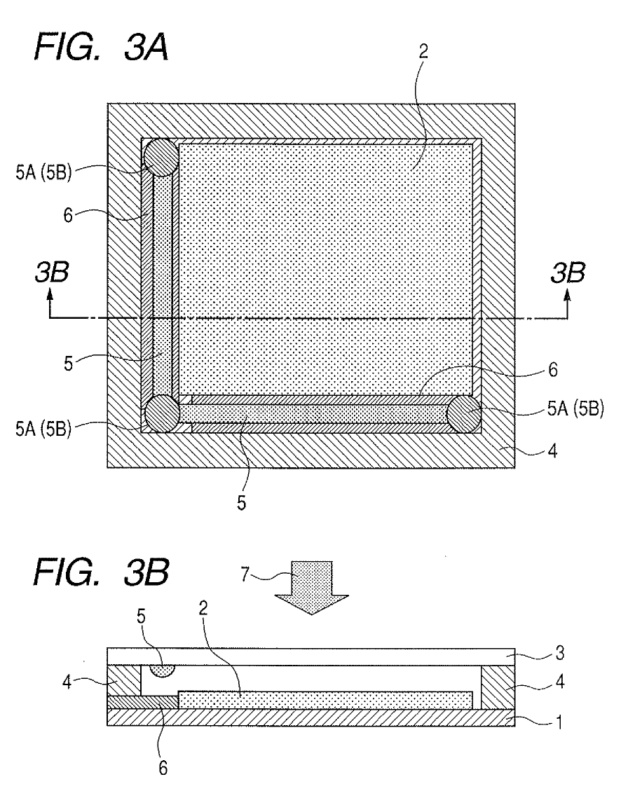

FIGS. 3A and 3B each show an example of Embodiment 3. FIG. 3A is a schematic plan view of an organic light emitting apparatus, and FIG. 3B is a schematic sectional view taken along the line 3B-3B of FIG. 3A. FIG. 3A is a schematic plan view when FIG. 3B is viewed from the observation direction 7, but the sealing substrate 3 is not shown in FIG. 3A in order that a planar constitution may be easily recognized. In addition, description similar to that of Embodiment 1 will be omitted.

The organic light emitting apparatus of this embodiment is also produced by steps similar to those of Embodiment 1 described above, but the moisture absorbing member 5 is formed on the drive circuit 6 formed so as to be in contact with two adjacent sides sandwiching a corner portion of the organic light emitting device 2. As a result, both the initial point 5A and end point 5B of the moisture absorbing member 5 are placed on the drive circuit 6. Accordingly, even when each of the initial point 5A and end point 5B of the moisture absorbing member 5 becomes thick, a non-light emitting region does not expand. Further, the organic light emitting apparatus produced by forming both the initial point and the end point of the moisture absorbing member on the drive circuit can make a larger area of a light emitting region than an organic light emitting apparatus produced by on the same size substrate, not forming the initial point and the end point on the drive circuit. Moreover, even when the end point 5B of the moisture absorbing member 5 changes into a stringy shape, the member does not contact with, for example, the organic light emitting device 2 or the adhesive 4, so the characteristics of the device are not adversely affected.

By the way, in the organic light emitting apparatus of this embodiment, the drive circuit 6 is formed up to a side edge portion of the substrate 1, and the planar sealing substrate 3 is bonded in such a manner that the adhesive 4 is in contact with part of the drive circuit 6.

### Embodiment 4

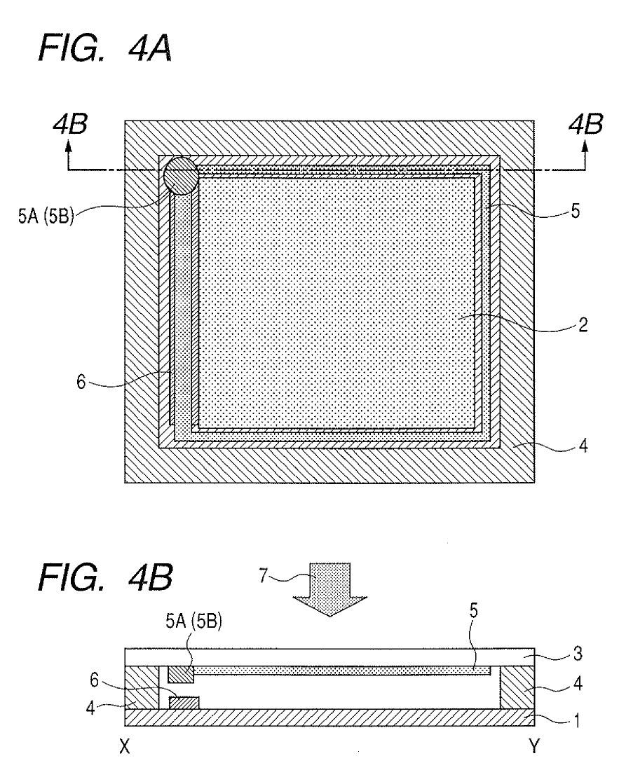

FIGS. 4A and 4B each show an example of Embodiment 4. FIG. 4A is a schematic plan view of an organic light emitting apparatus, and FIG. 4B is a schematic sectional view taken along the line 4B-4B of FIG. 4A. Although FIG. 4A is a schematic plan view when FIG. 4B is viewed from the observation direction 7, the sealing substrate 3 is not shown in FIG. 4A in order that a planar constitution may be easily recognized. In addition, description similar to that of Embodiment 1 will be omitted.

This embodiment is different from Embodiment 1 in the following points: in FIG. 4A, a moisture absorbing member 5A is present at a corner of the sealing substrate 3, and the sealing substrate 3 is a planar member.

The moisture absorbing member 5A is placed in a gap between the drive circuit 6 and the sealing substrate 3, and a wide region corresponding to the thickening of each of the initial point 5A and end point 5B of the moisture absorbing member 5, and to the deformation of the moisture absorbing member 5 can be secured. In addition, a moisture absorbing member 5B is also placed in a gap between the drive circuit 6 and the sealing substrate 3. As a result, none of both the moisture absorbing members 5A and 5B contacts with, for example, the organic light emitting device 2 or the adhesive 4, so the characteristics of the device are not affected. In addition, an area occupied by the entirety of the moisture absorbing members, in other words, a non-light emitting region can be narrowed. As a result, the light emitting region of the organic light emitting apparatus can be expanded. Further, the organic light emitting apparatus produced by forming both the initial point and the end point of the moisture absorbing member on the drive circuit can make a larger area of a light emitting region than an organic light emitting apparatus produced by on the same size substrate, not forming the initial point and the end point on the drive circuit.

### Embodiment 5

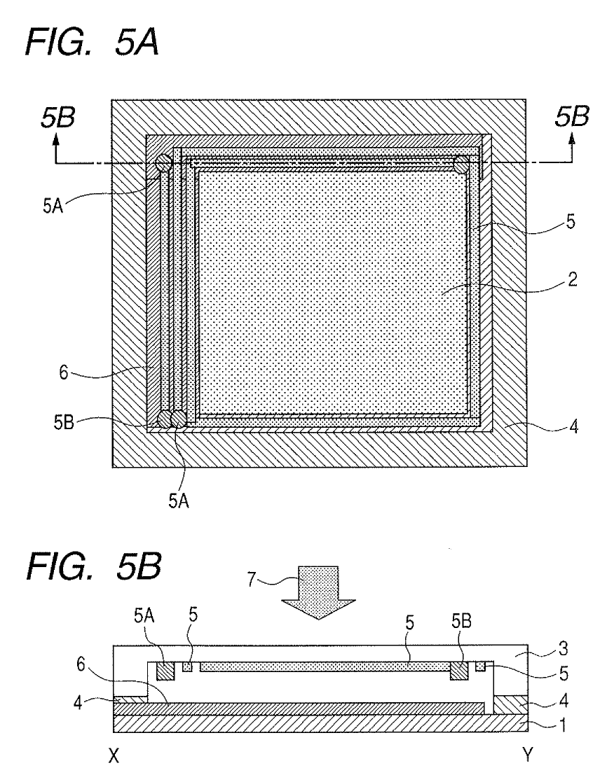

FIGS. 5A and 5B each show an example of Embodiment 5. FIG. 5A is a schematic plan view of an organic light emitting apparatus, and FIG. 5B is a schematic sectional view taken along the line 5B-5B of FIG. 5A. FIG. 5A is a schematic plan view when FIG. 5B is viewed from the observation direction 7, but the sealing substrate 3 is not shown in FIG. 5A in order that a planar constitution may be easily recognized. In addition, description similar to that of Embodiment 1 will be omitted.

This embodiment is different from Embodiment 1 in the following points: in FIG. 5A, the moisture absorbing member 5A is present at a corner of the sealing substrate 3, the drive circuit 6 is present on two sides, part of the drive circuit 6 is in contact with the adhesive 4, and a plurality of the moisture absorbing members 5B is placed on one side of the sealing substrate 3.

The moisture absorbing member 5A is placed in a gap between the drive circuit 6 and the sealing substrate 3, and a wide region corresponding to the thickening of each of the initial point 5A and end point 5B of the moisture absorbing member 5, and to the deformation of the moisture absorbing member 5 can be secured. In addition, a moisture absorbing member 5B is also placed in a gap between the drive circuit 6 and the sealing substrate 3. As a result, none of both the moisture absorbing members 5A and 5B contacts with, for example, the organic light emitting device 2 or the adhesive 4, so the characteristics of the device are not affected. In addition, an area occupied by the entirety of the moisture absorbing members, in other words, a non-light emitting region can be narrowed. As a result, the light emitting region of the organic light emitting apparatus can be expanded. Further, the organic light emitting apparatus produced by forming both the initial point and the end point of the moisture absorbing member on the drive circuit can make a larger area of a light emitting region than an organic light emitting apparatus produced by on the same size substrate, not forming the initial point and the end point on the drive circuit.

### Embodiment 6

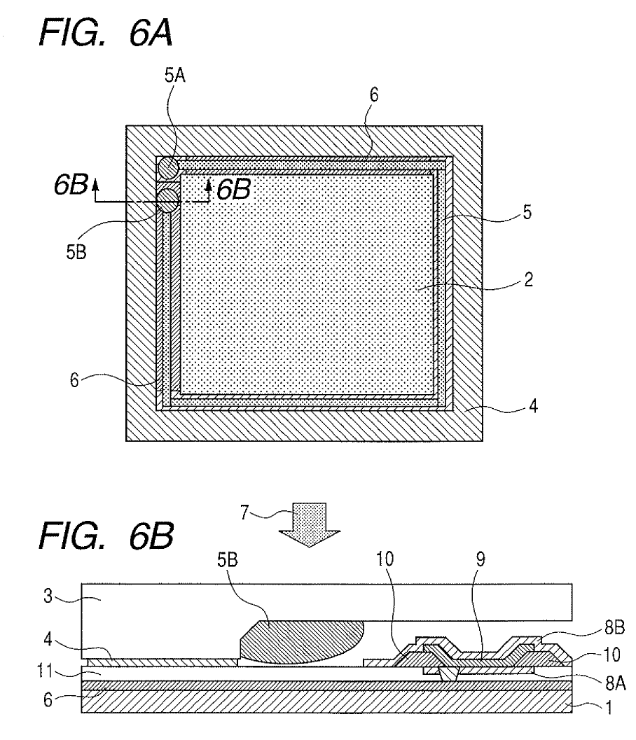

FIGS. 6A and 6B each show an example of Embodiment 6. FIG. 6A is a schematic plan view of an organic light emitting apparatus, and FIG. 6B is a schematic sectional view taken along the line 6B-6B of FIG. 6A. In FIGS. 6A and 6B, reference symbols 8A and 8B each represent an electrode; 9, an organic compound layer; 10, a device separating layer; and 11, a protective layer. FIG. 6A is a schematic plan view when FIG. 6B is viewed from the observation direction 7, but the sealing substrate 3, the electrodes 8, the device separating layer 10, and the protective layer 11 are not shown in FIG. 6A in order that a planar constitution may be easily recognized. In addition, description similar to that of Embodiment 1 will be omitted.

In FIG. 6B, the drive circuit 6 is placed on the substrate 1, and the drive circuit 6 is connected to the first electrode 8A. In addition, the protective layer 11 is placed on the drive circuit 6. The organic compound layer 9 is placed in a gap between the first electrode 8A and the second electrode 8B. In addition, adjacent organic light emitting devices are separated from each other by the device separating layer 10. The initial point 5A and end point 5B of the application of the moisture absorbing member are placed in a gap between the drive circuit 6 and the sealing substrate 3 so as to be in contact with the sealing substrate 3. The sealing substrate 3 is in contact with the protective layer 10 through the adhesive 4.

A gap between the second electrode 8B and the sealing substrate 3 is narrower than the gap where the moisture absorbing member 5 is placed. In addition, it is not appropriate that the moisture absorbing member 5 be placed on the organic light emitting device 2 because the member hinders the light emission of the apparatus when viewed from the observation direction.

Accordingly, the gap between the drive circuit 6 and the sealing substrate 3 is an appropriate wide region which: does not hinder the light emission; and corresponds to the thickening of each of the initial point 5A and end point 5B of the moisture absorbing member 5, and to the deformation of the moisture absorbing member 5. In addition, part of the moisture absorbing members 5B are also placed in the gap between the drive circuit 6 and the sealing substrate 3. As a result, none of both the initial point 5A and the end point 5B contacts with, for example, the adhesive 4, the electrodes 8, the organic compound layer 9, the device separating layer 10, or the protective layer 11, so the characteristics of the device are not affected. In addition, an area occupied by the entirety of the moisture absorbing members, in other words, a non-light emitting region can be narrowed. As a result, the light emitting region of the organic light emitting apparatus can be expanded. Further, the organic light emitting apparatus produced by forming both the initial point and the end point of the moisture absorbing member on the drive circuit can make a larger area of a light emitting region than an organic light emitting apparatus produced by on the same size substrate, not forming the initial point and the end point on the drive circuit.

The embodiments of the present invention have been described above, but the present invention is not limited to the constitution of each of the embodiments. The organic light emitting apparatus of the present invention may be the so-called bottom emission type apparatus in which light is extracted from a device substrate side as well as the so-called top emission type apparatus in which light is extracted from a sealing substrate side as described in each embodiment; provided that the top emission type apparatus can emit light better than the bottom emission type apparatus because a moisture absorbing member does not shield light emission as described in each of the above-mentioned embodiments.

The organic light emitting apparatus according to the present invention is applicable to, for example, a display apparatus which: has formed in itself plural light emitting device groups each formed of light emitting devices for three colors, that is, R, G, and B colors; and can display colors. The organic light emitting apparatus of the present invention can be used as a pixel portion of, in particular, an active matrix driven display apparatus out of the display apparatuses. The apparatus can be preferably used as a display apparatus in, for example, a television set, the display portion of a computer, the display portion of a cellular phone, the display portion of a personal digital assistant (PDA), the display portion of a portable music player, the electronic view finder portion of an imaging device, or the display portion of a car navigation system.

Next, examples and comparative examples of the described embodiments will be described.

### EXAMPLE 1

A method of producing the organic light emitting apparatus shown in each of FIGS. 1A and 1B will be described.

The drive circuit 6 is produced on the substrate 1 with a sputtering apparatus, an etching apparatus, or the like by technologies such as photolithography and wet development.

A silver film having a thickness of 200 nm and an indium zinc oxide (IZO) film having a thickness of 0.6 nm are laminated to be connected to the drive circuit 6, whereby a first electrode (not shown) is produced. The first electrode is subjected to UV/ozone cleaning and conveyed to a vacuum vapor deposition apparatus, and the apparatus is evacuated to a degree of vacuum of 1×10⁻⁶ Torr.

After that, N,N′-di(1-naphtyl)-N,N′-diphenylbenzidine (α-NPD) represented by the following formula is formed into a film having a thickness of 50 nm on the first electrode, whereby a hole transporting layer is produced.

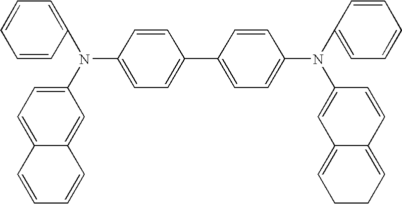

Subsequently, a co-vapor-deposited film of coumarin 6 represented by the following formula and tris[8-hydroxyquinolinato]aluminum (Alq3), the film having a thickness of 30 nm, is formed on the hole transporting layer, whereby a light emitting layer is produced.

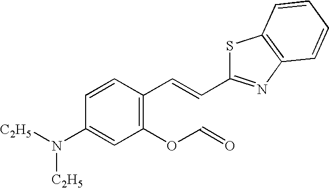

Next, a phenanthroline compound represented by the following formula is formed into a film having a thickness of 10 nm on the light emitting layer, whereby an electron transporting layer is produced.

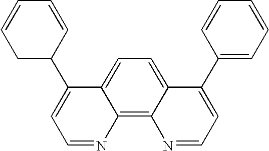

Further, a co-vapor-deposited film of cesium carbonate and the phenanthroline compound represented by the above formula, the film having a thickness of 40 nm, is formed, whereby an electron injecting layer is produced. The hole transporting layer, the light emitting layer, the electron transporting layer, and the electron injecting layer described above form the organic compound layer.

Subsequently, the substrate obtained in the above step is conveyed to a sputtering apparatus, and indium tin oxide (ITO) is formed into a film having a thickness of 220 nm on the electron injecting layer so as to be connected to the drive circuit 6. The film is defined as the second electrode (not shown), whereby an organic light emitting device is produced.

Meanwhile, the sealing substrate 3 in which a recessed portion is formed is produced by employing a method such as etching or sand blast.

The moisture absorbing member 5 (PT-DESICCANT No. 32 manufactured by Shinagawa Chemicals Co., Ltd.) is applied onto the sealing substrate 3 with a drawing applicator (SHOT MINI manufactured by MUSASHI ENGINEERING, INC.). At this time, the viscosity of the moisture absorbing member is 4.0×10⁴ cP. A needle having an inner diameter of 0.42 mm is used, a pressure of 0.1 MPa is applied to the needle, the member is applied at a rate of 35 mm/sec, and a distance between the tip of the needle and the sealing substrate 3 is 0.2 mm.

At that time, the application is initiated from a position above the drive circuit 6 in a state where the substrate 1 and the sealing substrate 3 are bonded to each other. A path during the application is as follows: the moisture absorbing member 5 circuits around the organic light emitting device 2 so that the moisture absorbing member 5 and the organic light emitting device 2 may not overlap when viewed from the observation direction 7. The ending point of the application is in the vicinity of the starting point of the application.

After the completion of the application, the resultant is dried at 120° C. for 30 minutes and then at 400° C. for 120 minutes. After the drying step, the resultant is conveyed to a vacuum vapor deposition apparatus. The adhesive 4 (manufactured by ThreeBond Co., Ltd.) is applied onto the peripheral wall portion of the sealing substrate 3 under an N₂ atmosphere in the vacuum vapor deposition apparatus.

Subsequently, the sealing substrate 3 is placed to cover the organic light emitting device 2 formed on the substrate 1. The substrate 1 and the sealing substrate 3 are bonded to each other with the adhesive 4, and the device substrate is covered with the sealing substrate 3. The adhesive 4 is irradiated with ultraviolet light having an energy of 3,000 mJ from a UV lamp so as to be cured.

When a voltage is applied to the drive circuit 6 of the organic light emitting apparatus, the apparatus can favorably emit light that does not degrade. In addition, the lifetime of the device is increased because the portion where the substrate 1 and the sealing substrate 3 are bonded to each other does not show any defect even when the apparatus is caused to emit light continuously. In addition, the area of a non-light emitting region is narrow, and a light emitting region is wide, so an apparatus capable of emitting light with good quality can be obtained.

### EXAMPLE 2

A method of producing the organic light emitting apparatus shown in each of FIGS. 2A and 2B will be described.

The organic light emitting apparatus is produced in the same manner as in Example 1 except that the position at which the moisture absorbing member 5 is applied is placed along one side of the organic light emitting device 2.

When a voltage is applied to the drive circuit 6 of the organic light emitting apparatus, the apparatus can favorably emit light that does not degrade. In addition, the lifetime of the device is increased because the portion where the substrate 1 and the sealing substrate 3 are bonded to each other does not show any defect even when the apparatus is caused to emit light continuously. In addition, the area of a non-light emitting region is narrow, and a light emitting region is wide, so an apparatus capable of emitting light with good quality can be obtained.

### EXAMPLE 3

A method of producing the organic light emitting apparatus shown in each of FIGS. 3A and 3B will be described.

First, the drive circuit 6 is produced in two regions on the substrate 1, in other words, the circuit is produced on two adjacent sides sandwiching a corner portion of the organic light emitting device 2 to be formed later. At this time, part of the drive circuit 6 is placed also at a position in contact with the adhesive 4 when the substrate 1 and the sealing substrate 3 are bonded to each other. Subsequent production steps for the device substrate are identical to those of Example 1.

Meanwhile, the moisture absorbing member 5 is applied to the planar sealing substrate 3 so that the member may be placed on the above-mentioned drive circuit 6 upon bonding of the sealing substrate 3 to the substrate 1. An apparatus to be used, and the conditions under which the member is applied are identical to those of Example 1.

Finally, the sealing substrate 3 is placed to cover the organic light emitting device 2 formed on the substrate 1. The substrate 1 and the sealing substrate 3 are bonded to each other with the adhesive 4, and the device substrate is covered with the sealing substrate 3.

When a voltage is applied to the drive circuit 6 of the organic light emitting apparatus, the apparatus can favorably emit light that does not degrade. In addition, the lifetime of the device is increased because the portion where the substrate 1 and the sealing substrate 3 are bonded to each other does not show any defect even when the apparatus is caused to emit light continuously. In addition, the area of a non-light emitting region is narrow, and a light emitting region is wide, so an apparatus capable of emitting light with good quality can be obtained.

### COMPARATIVE EXAMPLE 1

A method of producing a conventional organic light emitting apparatus will be described.

This comparative example is different from Example 1 in a point concerning the initial point 5A and end point 5B of the moisture absorbing member 5, and the other steps for the production of the organic light emitting apparatus except for the point are identical to those of Example 1.

The moisture absorbing member 5 is applied onto the sealing substrate 3 having a recessed portion. At this time, the moisture absorbing member 5 is applied so that none of the initial point 5A and the end point 5B may be placed on the drive circuit 6 when the substrate 1 and the sealing substrate 3 are bonded to each other. The initial point 5A of the moisture absorbing member 5 is widened when viewed from the observation direction 7. In addition, the end point 5B of the moisture absorbing member 5 shows a stringy shape when a drawing applicator moves away from the sealing substrate 3, and part of the end point contacts with the region where the adhesive 4 is placed.

After that, the substrate 1 and the sealing substrate 3 are bonded to each other as in Example 1, whereby the organic light emitting apparatus is obtained.

When a voltage is applied to the drive circuit 6 of the organic light emitting apparatus, part of the initial point 5A of the moisture absorbing member 5 overlaps the organic light emitting device 2 when viewed from the observation direction 7, and the overlapping serves as a defect in light emission. In addition, when the apparatus is caused to emit light by being continuously driven, the end point 5B of the moisture absorbing member 5 mixes in a space between the adhesive 4 and the substrate 1, whereby the device is insufficiently sealed with the sealing substrate, and the lifetime of the device is reduced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2006-337847, filed Dec. 15, 2006, and No. 2007-295265 Nov. 14, 2007, which are hereby incorporated by reference herein in their entirety.

What is claimed is:

1. An organic light emitting apparatus comprising:
a substrate;
an organic light emitting device formed on the substrate and having a first electrode, an organic compound layer, and a second electrode in a stated order from a side of the substrate;
a drive circuit which is formed on at least one side of the organic light emitting apparatus outside a region on the substrate where the organic light emitting device is formed and which controls light emission of the organic light emitting device;
a sealing substrate for sealing the organic light emitting device between the substrate and itself; and
a moisture absorbing member applied linearly to an outer peripheral portion of the sealing substrate, the moisture absorbing member being applied from a starting point to an ending point, and both the starting point and the ending point being placed on the side where the drive circuit is formed.

2. The organic light emitting apparatus according to claim 1, wherein the drive circuit is formed on one side, and the starting point and ending point of the application of the moisture absorbing member are each formed on the one side.

3. The organic light emitting apparatus according to claim 1, wherein the moisture absorbing member is formed only on the side having the drive circuit.

4. A method of producing an organic light emitting apparatus, comprising:
forming a first electrode, an organic compound layer, and a second electrode in a stated order on a substrate to form an organic light emitting device;
forming a drive circuit for controlling light emission of the organic light emitting device on at least one side of the organic light emitting apparatus outside a region on the substrate where the organic light emitting device is formed;
applying a moisture absorbing member having a viscosity linearly to an outer peripheral portion of a sealing substrate; and
bonding the sealing substrate to the substrate so that each of a starting point and an ending point of the application of the moisture absorbing member is placed on the side where the drive circuit is formed.
